(19) United States
(12) Patent Application Publication
(10) Pub. No.: US 2023/0337397 A1
(43) Pub. Date: Oct. 19, 2023

(54) INTEGRATED VAPOR CHAMBER AND HEAT SINK

(71) Applicant: Meta Platforms, Inc., Menlo Park, CA (US)

(72) Inventors: Jayati Athavale, Mountain View, CA (US); Mohammad Nikoukar, Sunnyvale, CA (US); Hussameddine Kabbani, San Jose, CA (US); Amin TermehYousefi, Mountain View, CA (US); Riocard De Los Santos, Mountain View, CA (US); Jones Udo-Akang, Hayward, CA (US)

(21) Appl. No.: 16/995,679

(22) Filed: Aug. 17, 2020

(51) Int. Cl. H05K 7/20

(52) U.S. Cl. CPC H05K 7/20309; H05K 7/205

(57) ABSTRACT

In an embodiment, an integrated vapor chamber and heatsink includes a heatsink portion and a vapor chamber portion. The vapor chamber portion is configured to interface with a heat source to be cooled, where the vapor chamber portion includes, on an internal surface of the vapor chamber portion, a wicking structure configured to transfer a working fluid within the vapor chamber portion. The heatsink portion, the vapor chamber portion, and the wicking structure are portions of a same single printed monobody structure.

### BACKGROUND OF THE INVENTION

The performance of electronic components such as computer chips is affected by its operating temperature. If components are not being cooled sufficiently, they do not perform as well. As electronic components become more powerful, they also tend to generate more heat. Data centers include server racks that each contain electronic components that generate heat. The heat can significantly degrade the performance of the data center, e.g., causing request handling to be slow, consuming large amounts of energy, and causing components to malfunction prematurely. Existing air cooling methods are becoming inadequate for maintaining an optimal temperature environment for electronic components or are impractical to use for cooling electronics.

### BRIEF DESCRIPTION OF THE DRAWINGS

Various embodiments of the invention are disclosed in the following detailed description and the accompanying drawings.

FIG. 1 is a diagram illustrating a conventional heatsink and vapor chamber assembly.

FIG. 2A is a perspective view of an embodiment of an integrated vapor chamber and heatsink.

FIG. 2B is a side view of an embodiment of an integrated vapor chamber and heatsink.

FIG. 2C is a top view of an embodiment of an integrated vapor chamber and heatsink.

FIG. 2D is a cross-sectional view of an embodiment of an integrated vapor chamber and heatsink.

FIG. 3 is a side view of an embodiment of an integrated vapor chamber and heatsink including grid-structured fins.

FIG. 4A is a cross-sectional view of a vapor chamber.

FIG. 4B is a cross-sectional view of a vapor chamber.

FIG. 5 is a cross-sectional view of a vapor chamber including a wick and slot.

FIG. 6 is a detailed view of a wick structure for a vapor chamber.

FIG. 7 is a flow chart illustrating an embodiment of a process for manufacturing an integrated heatsink and vapor chamber.

FIG. 8A is a schematic diagram of a process for manufacturing an integrated heatsink and vapor chamber.

FIG. 8B shows a detailed view of a section of an integrated heatsink and vapor chamber manufactured using the process of FIG. 7.

FIG. 9 shows examples of measurements and dimensions (in mm) of an integrated heatsink and vapor chamber in some embodiments.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

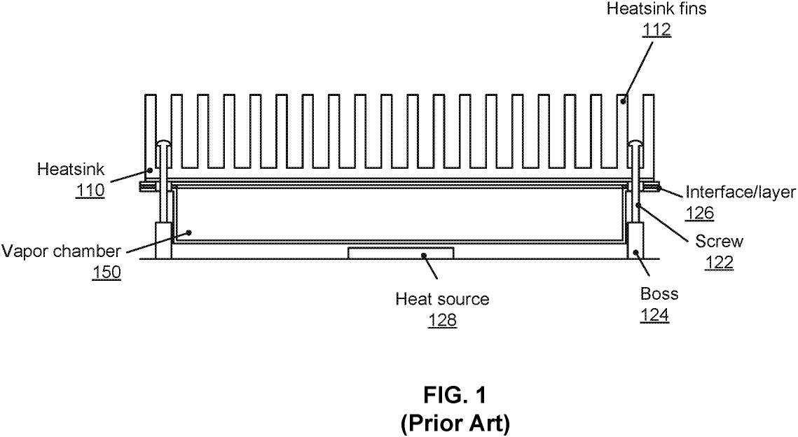

FIG. 1 is a diagram illustrating a conventional heatsink and vapor chamber assembly. Vapor chamber 150 is a passive heat transfer device that employs evaporative (two-phase) cooling. Heatsink 110 is a passive heat exchanger that transfers heat away from a heat source 128 such as an electronic component (central processing unit or CPU). The heatsink and vapor chamber assembly is typically coupled to each other and/or to a board or device by a screw 122 and boss 124 as shown. Boss 124 on the board/device receives the screw 122 to position the heatsink and vapor chamber assembly in close proximity to the heat source 128 so that the heat source can be cooled.

In the heatsink and vapor chamber assembly shown here, vapor chamber 150 removes heat from heat source 128 and transfers it to the attached heatsink 110 via conduction. The heatsink in turn rejects the heat to air typically via forced convection. The heatsink has a typical fin arrangement in which fins 112 are arranged parallel to each other along the length of the heatsink. Each fin 112 is a flat plate that allows heat to flow from one end to be dissipated as it travels to the other end.

Heatsink 110 and vapor chamber 150 are bonded together by soldering, brazing, or the like, which creates an interface/layer between the heatsink and the vapor chamber. This interface 126 introduces an extra layer of thermal resistance known as contact resistance. This thermally resistant layer means that the heatsink and vapor chamber assembly does not dissipate heat as well as an assembly that does not have such a layer.

Unlike the heatsink and vapor chamber assembly shown in FIG. 1, the disclosed integrated vapor chamber and heatsink is a monobody structure. In various embodiments, the monobody structure is produced by a 3D printing technique such as Direct Metal Laser Sintering (DMLS). In one aspect, by 3D printing both parts as a monobody, the interface can be eliminated to improve the heat dissipation performance of an integrated vapor chamber and heatsink.

In another aspect, 3D printing allows for better control of the heatsink fin design including the thickness of fins and gaps between fins. Currently, the smallest fin thickness that can be achieved by conventional techniques is around 0.2 mm and the smallest fin gap is around 1.1 mm. By contrast, the disclosed techniques can produce even smaller fin thicknesses of around 0.15 mm and fin gaps of around 0.8 mm. The smaller fin thicknesses and fin gaps obtained by the disclosed techniques improve heat transfer and thus reduce the overall thermal resistance of the heatsink and, correspondingly, the integrated heatsink and vapor chamber assembly.

In another aspect, the monobody structure eliminates the need for a coupler such as screw 122. This enhances the durability and mechanical strength of the integrated heatsink and vapor chamber. In addition, maintenance is easier and less costly because no screw (or other similar component) is required.

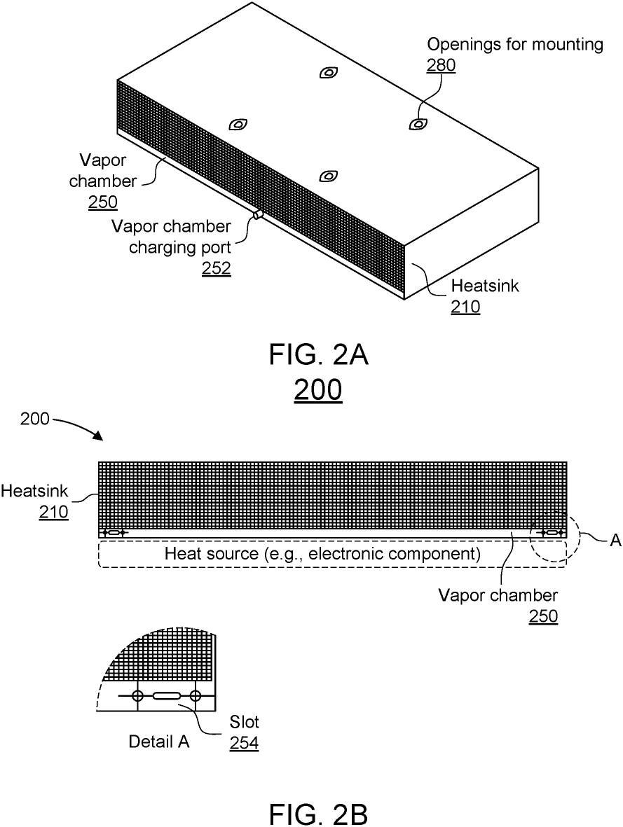

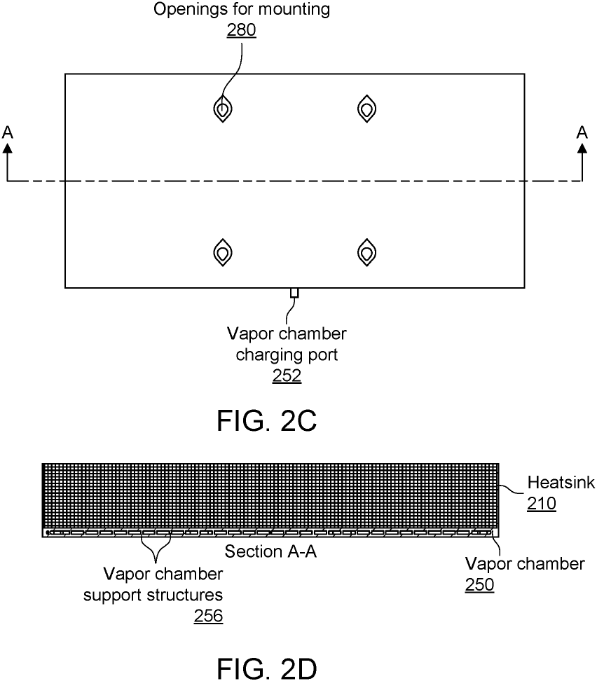

FIG. 2A is a perspective view of an embodiment of an integrated vapor chamber and heatsink. The apparatus 200 includes a heatsink portion 210 (sometimes simply called “heatsink”) and a vapor chamber portion 250 (sometimes simply called “vapor chamber”). Vapor chamber portion 250 is configured to interface with a heat source to be cooled. For example, an electronic component such as a computer processor can be cooled by bringing the vapor chamber into close proximity or contact with the electronic component. Vapor chamber portion 250 includes, on an internal surface of the vapor chamber, a wicking structure configured to transfer a working fluid within the vapor chamber as further described below.

In this view, vapor chamber portion 250 is on the bottom of the apparatus, and the heatsink portion 210 is contacting and provided above the vapor chamber portion. Both portions run the entire length of the apparatus at least in in this example. Openings for mounting 280 are configured to receive and align fasteners (such as screws) to attach the integrated heatsink and vapor chamber to a component to be cooled or to hardware such as a server rack to cool components of the server rack. Also shown is a vapor chamber charging port 252 that is configured to permit the vapor chamber to be charged as further described herein.

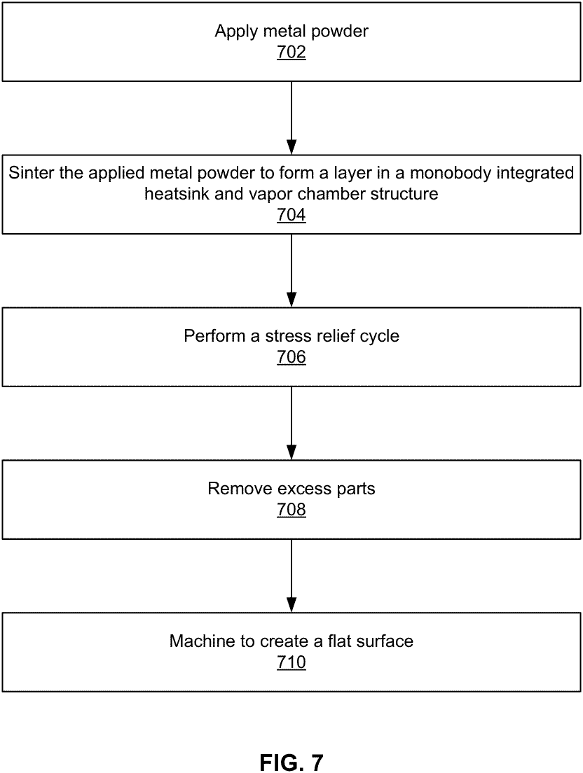

Heatsink portion 210, vapor chamber portion 250, and the wicking structure are portions of a same single printed monobody structure. In various embodiments, the single printed monobody structure is printed using Direct Metal Laser Sintering (DMLS), an example of which is shown in FIG. 7.

FIG. 2B is a side view of an embodiment of an integrated vapor chamber and heatsink. In this view, a heat source such as electronic component to be cooled using the integrated vapor chamber and heatsink is shown. In various embodiments, a first side of the vapor chamber portion 250 is configured to interface the heat source and a second side of the vapor chamber opposite the first side is configured to interface with the heatsink portion 210.

In various embodiments, the vapor chamber portion 250 includes one or more slots as depicted in Detail View A. The slot 254 permits trapped metal powder to be evacuated from the vapor chamber during a manufacturing process as further described below.

FIG. 2C is a top view of an embodiment of an integrated vapor chamber and heatsink. The top view shows four openings 280 for mounting the integrated vapor chamber and heatsink to devices, surfaces, or electronic components to be cooled. This view also shows an example of a vapor chamber charging port 252. Although depicted at the center of the vapor chamber portion for symmetry, the number and placement of the charging port is merely exemplary and not intended to be limiting. A view of section A-A is shown in the following figure.

FIG. 2D is a cross-sectional view of an embodiment of an integrated vapor chamber and heatsink. For context, the relative positions of heatsink portion 210 and vapor chamber portion 250 are shown. These components are like their counterparts described herein. Also visible in this view are vapor chamber support structures 256. In this example, the support structures 256 run along the length of the vapor chamber portion to provide structural integrity. For example, during operation of the vapor chamber, sometimes a vacuum is created and the support structures prevent the walls of the vapor chamber from collapsing.

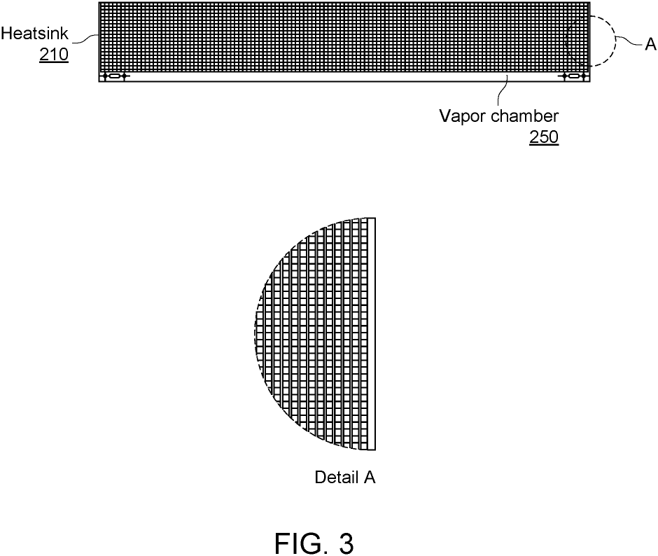

FIG. 3 is a side view of an embodiment of an integrated vapor chamber and heatsink including grid-structured fins. For context, the relative positions of heatsink portion 210 and vapor chamber portion 250 are shown. Heatsink portion 210 includes a plurality of horizontal fins and a plurality of vertical fins forming a grid structure as depicted in Detail A. This grid arrangement increases the surface area of the heatsink, which increases the ability of the heatsink to dissipate heat. This grid-structure fin has better fin efficiency compared with a typical heatsink fin arrangement such as the one shown in FIG. 1 in which fins are parallel to each other but not arranged in a grid-like structure.

In various embodiments, the heatsink is a rectangular/square grid extruded over the length/width of the apparatus. In various embodiments, the fin thickness is around 0.15 mm and/or each gap between fins is around 0.8 mm. In a square grid, the gaps is 0.8 mm × 0.8 mm. As further described below, the 3D printing techniques permit fins of these thicknesses and gaps to be produced. These smaller fin thicknesses and gaps improves heat transfer compared with conventional heatsinks.

The sizes and spacing of the heatsink fins can be selected depending on the cooling application. For example, the heatsink grid can be sized (spacing between fins, fin thicknesses, etc.) for the expected heat generated by an electronic component to cooled or for a desired level of cooling to be provided by the integrated heatsink and vapor chamber.

In various embodiments, a top portion of the heatsink at least in part encloses the grid structure. The view shown in FIG. 2A also shows an example of how a top portion of the heatsink encloses the grid structure. This arrangement creates a flat enclosing surface (besides the holes 280 for mounting screws to pass through) for added structural integrity, better handling, air flow redirection, and added surface area and thermal mass.

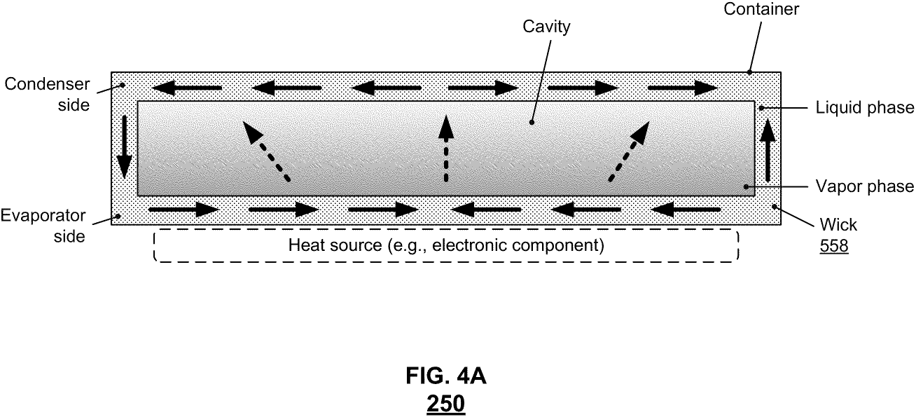

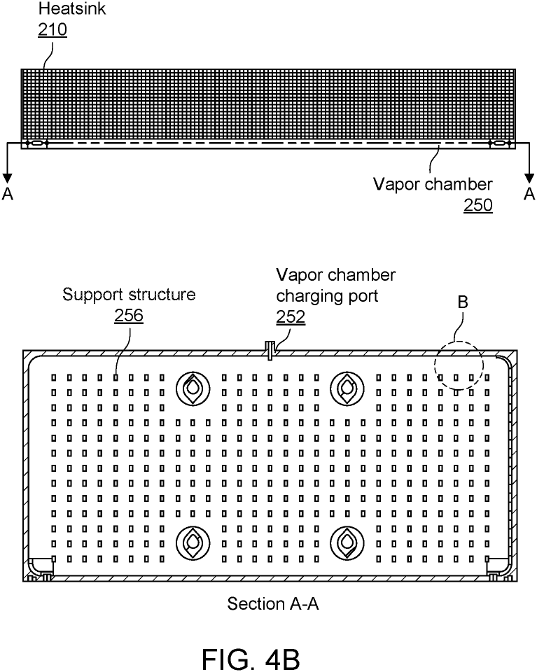

FIG. 4A is a cross-sectional view of a vapor chamber. This vapor chamber is an example of vapor chamber 250. The vapor chamber includes a container that is hermetically sealed to prevent leakage, which decreases the heat transfer coefficient. Within the container is a cavity whose walls have a wick structure 558 that provides capillary pressure to transfer working fluid in liquid phase from a condenser side to an evaporator side. The dashed arrows show vapor flow from the evaporator side to the condenser side. The solid arrows show liquid flow back to the evaporator side through the wick.

The two-phase process (evaporation and condensation) works as follows. The working fluid in liquid state absorbs heat from the evaporator side and converts the liquid to vapor phase. The vapor rises through the vapor chamber cavity and reaches the condenser side where it rejects heat to the condenser and converts the vapor back to liquid phase. The working fluid is then transported back to the evaporator side via the wick structure. The heat-transfer coefficients associated with evaporation and condensation processes (two-phase processes) are relatively high, resulting in higher thermal conductivity than some other cooling techniques.

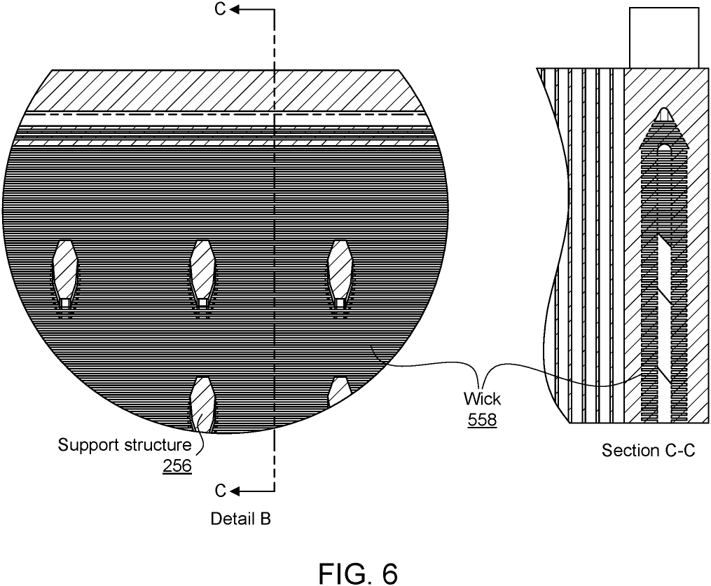

FIG. 4B is a cross-sectional view of a vapor chamber. For context, the relative positions of heatsink portion 210 and vapor chamber portion 250 are shown. Cross section A-A shows various features of the vapor chamber including a charging port 252 by which the vapor chamber is vacuum charged. Vapor chamber 250 includes a plurality of support structures 256 corresponding to the ones described with respect to FIG. 2D. The support structures are the white dots dispersed throughout the vapor chamber. Detail B is further described with respect to FIG. 6.

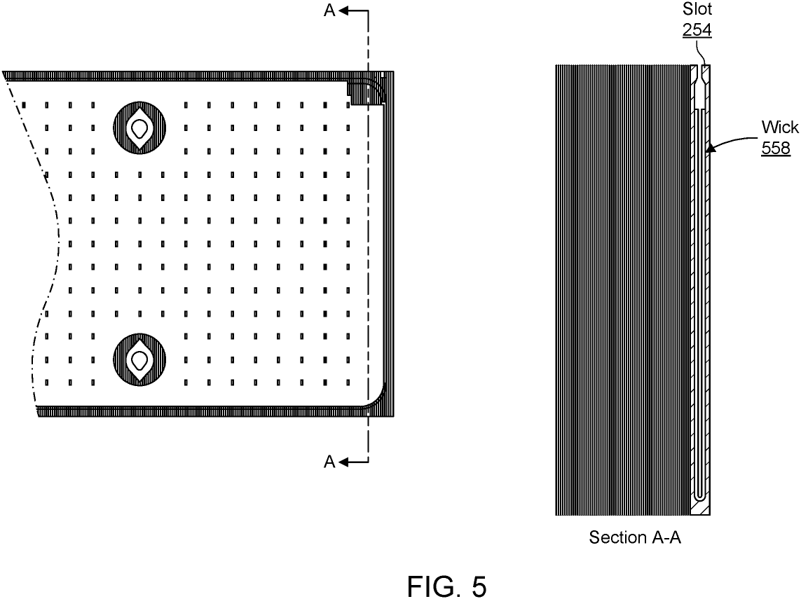

FIG. 5 is a cross-sectional view of a vapor chamber including a wick and slot. Cross section A-A shows slot 254 and wick 558. Slot 254 allows trapped metal powder to be evacuated as described with respect to FIG. 2B.

Wick 558 transports fluid within the vapor chamber. In various embodiments, the wick structure provides texture on the walls of the vapor chamber to transport fluid. The ability of the wick to transport fluid (e.g., rate at which fluid is transported) can be varied by changing properties of the wick. For example, in various embodiments, the wick includes microgrooves. The microgrooves act as channels to transport working fluid. The size (depth) and spacing of microgrooves can be varied depending on a desired property of the wick. As another example, the porosity of the wick can be selected to vary in certain regions.

The wick design (material, structure, porosity for example) can take into consideration the type of working fluid and vice versa. In various embodiments, the working fluid is water. Various charging ratios such as ones ranging from 30-50% may be used. In various embodiments, the vapor chamber has a height of 6.2 mm. The height of the vapor chamber can be selected to correlate to desired vapor chamber performance or varied based on space constraints.

FIG. 6 is a detailed view of a wick structure for a vapor chamber. This view corresponds to the area labeled “B” in FIG. 4B. In various embodiments, the support structure 256 is a pillar that runs from the top to the bottom of the vapor chamber. One or more support structures may be provided, for example in parallel with each other to support the chamber and prevent mechanical failure. The number and placement (spacing) is merely exemplary and not intended to be limiting. For example, more pillars or pillars with a larger diameter can increase structural strength. However, this decreases internal vapor chamber volume available for the working fluid which may result in reduction in vapor chamber performance.

Cross section C-C shows a close-up view of wick 558. In various embodiments, the wicking structure includes grooved channels adapted to transport the working fluid as shown. In various embodiments, the wicking structure includes a mesh. The wicking structure can be made by sintering metal powder particles as further described below.

The heatsink and the vapor chamber can be made of a variety of materials. For example, the heatsink and/or the vapor chamber is copper or aluminum. The heatsink and the vapor chamber can be made of the same material or of different materials. In various embodiments, at least a portion of the heatsink is made of a different material from at least a portion of a body of the vapor chamber. Copper has relatively high thermal conductivity but is relatively heavier compared with aluminum. Thus, whether (at a least a portion of) the integrated heatsink and vapor chamber is copper or aluminum can be selected based on preferences for portability vs. heat dissipation performance. In one example, the heatsink fins are aluminum (to reduce weight) while the vapor chamber is copper because the vapor chamber attaches directly to heat source to be cooled and would benefit from the higher conductivity of the copper. The working fluid can be selected to be compatible with the type of material. For example, water is a compatible working fluid for a copper vapor chamber. Alcohol is a compatible working fluid for an aluminum vapor chamber.

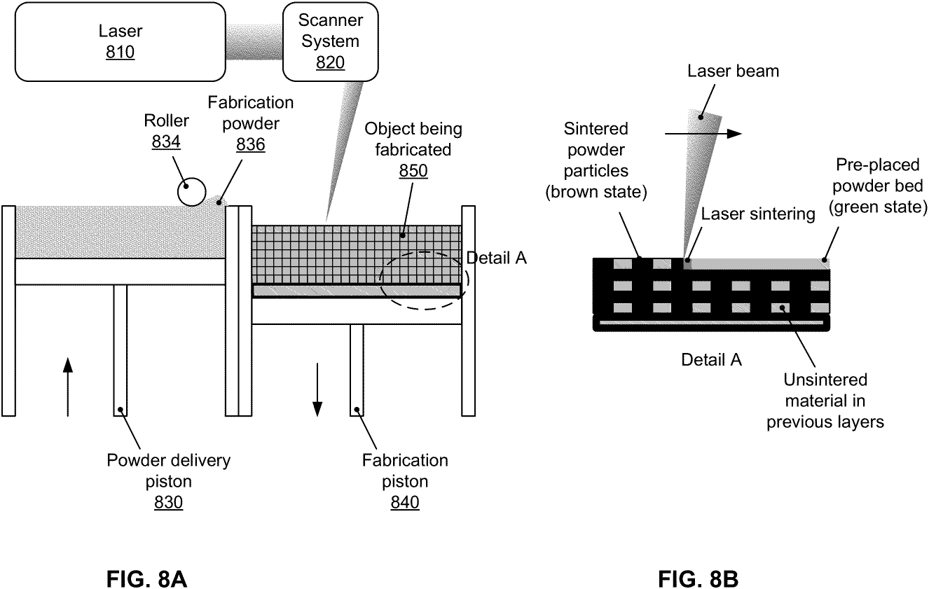

FIG. 7 is a flow chart illustrating an embodiment of a process for manufacturing an integrated heatsink and vapor chamber. This process may be implemented on a system such as the one shown in FIG. 8A. This process can be used to print a variety of geometries including both open (e.g., heatsink/fins) and closed structures (e.g., vapor chamber) as well as an apparatus that includes both open and closed structures. The process works well for printing intricate structures such as the heatsink described herein with closely-spaced and relatively thin fins as well as enclosed structures with texture (wick) such as the vapor chamber described herein. The same process can be applied to print an integrated monobody heatsink and vapor chamber. The process also works well for a variety of materials including a highly reflective material such as copper.

In various embodiments, the process receives as input a specification of an apparatus to be printed such as a CAD drawing or instructions formed based on a CAD drawing. The process will be described using the example of the integrated heatsink and vapor chamber as the apparatus being printed, but this is not intended to be limiting as the process can be used to print other types of apparatuses. The process will be described with the aid of FIGS. 8A and 8B. FIG. 8A is a schematic diagram of a process for manufacturing an integrated heatsink and vapor chamber. FIG. 8B shows a detailed view of a section of an integrated heatsink and vapor chamber manufactured using the process of FIG. 7.

The system of FIG. 8A includes a laser 810, scanner system 820, powder delivery piston 830, and fabrication piston 840. Laser 810 is configured to provide a heat source for melting metal powder. Scanner 820 is configured to control a laser beam to direct the laser beam in a desired direction or pattern. Powder delivery piston 830 is configured to deliver powder during the fabrication process, while fabrication piston 840 is configured to receive the powder from the powder delivery piston and support a part being fabricated. The powder delivery piston starts in a lowered position and gradually moves up to deliver fabrication powder 836, which gets pushed by roller 834 over the edge to land on fabrication piston 840. The fabrication piston starts in an elevated position and gradually moves down to accommodate a growing size of the component being manufactured.

Returning to FIG. 7, the process begins by applying metal powder (702). Referring to FIG. 8A, metal powder is applied one layer (cross-section) at a time by delivering a pre-determined amount of fabrication powder 836 to the fabrication piston 840. For example, powder delivery piston 830 moves up by a predetermined amount and roller 834 (or similar powder moving device) rolls across the fabrication powder 836 to displace the powder over the edge separating the powder delivery area from the fabrication area to land on the fabrication piston 840. In various embodiments, a single layer or cross-section is around 30, 50, or 80 microns. The size of the layer can be pre-determined or pre-selected based on the apparatus to be manufactured.

Returning to FIG. 7, the process sinters the applied metal powder to form a layer in a monobody integrated heatsink and vapor chamber structure (704). A vapor chamber portion of the monobody structure includes on an internal surface of the vapor chamber portion a wicking structure configured to transfer a working fluid within the vapor chamber portion. Referring to FIGS. 8A and 8B, sintering is performed by directing laser 810 using scanner system 820. As shown, scanner system 820 directs a laser beam in a desired pattern across the layer of fabrication powder, melting portions of the fabrication powder to create a layer of the object being fabricated 850. The portion to be melted is according to a specification. For example, a scanner system controls the direction of the laser beam by manipulating mirrors inside the scanner to direct the laser beam in a desired direction. The laser beam (or other powder melting mechanism) can be controlled in other ways. The lighter sections are powder in green state, while the darker sections are sintered (melted) powder particles in brown state. In this example, the heat fins have a grid-structure so in a given layer, sintered powder alternate with un-sintered powder as shown. Un-sintered powder that becomes trapped can be removed as further described below.

The powder delivery piston 830 moves up during the course of fabrication, and the fabrication piston 840 moves down to accommodate the growing size of the object being fabricated 850. The object being fabricated 850 in this example is a monobody integrated heatsink and vapor chamber. Upon completion of all the layers, the object is removed from the fabrication piston.

Returning to FIG. 7, the process performs a stress relief cycle (706). The stress relief cycle heats the apparatus to a predetermined temperature to relieve any internal stresses on an apparatus from a manufacturing process. In various embodiments, performing the stress relief cycle includes removing the monobody integrated heatsink and vapor chamber from a fabrication piston, and heating the monobody integrated heatsink and vapor chamber.

The process removes excess parts (708). Depending on the type of apparatus being manufactured by the process, sacrificial parts such as temporary support parts may be made. These sacrificial parts are removed for example by cutting them off.

In various embodiments, removing excess parts includes evacuating trapped metal powder from the vapor chamber via a slot in the vapor chamber such as slot 254 described with respect to FIG. 2B. Any excess powder from the heatsink is also removed. Excess powder can be removed using a variety of techniques such as shaking the apparatus, blowing compressed air through the apparatus, or applying chemicals. Excess powder can be removed prior to the stress relief cycle and recycled for future use.

The process machines the apparatus to create a flat surface on a bottom of the monobody integrated heatsink and vapor chamber (710). For example, the apparatus is cut to create a flat surface/bottom suitable for cooling a heat generating component. Machining can be performed before or after charging the vapor chamber.

In various embodiments, the process further includes charging and sealing the vapor chamber. Referring to FIG. 4A, the cavity of the vapor chamber is evacuated to remove any residual metal powder (as described with respect to 708) and then charged with an internal working fluid. As described herein, the amount/level of charge can be optimized for the desired cooling application of the vapor chamber.

The process described here overcomes some of the challenges of 3D printing a monobody heatsink and vapor chamber and enables both a relatively intricate open structure like the heatsink and a closed structure like the vapor chamber to be printed using the same process.

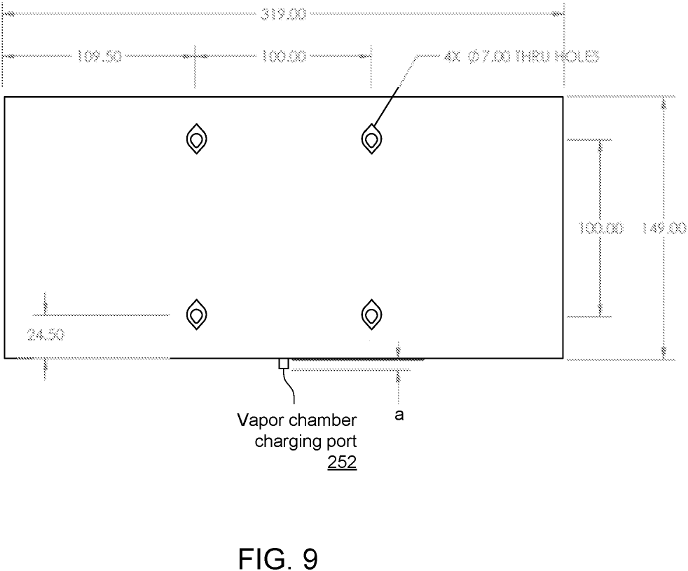

FIG. 9 shows examples of measurements and dimensions (in mm) of an integrated heatsink and vapor chamber in some embodiments. The heatsink includes at least one of: a fin thickness of between 0.15 mm and 0.2 mm or a fin gap between 0.6 mm and 1.1 mm.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A device comprising:
a heatsink portion including a plurality of horizontal fins and a plurality of vertical fins forming a grid structure, wherein at least one fin of the plurality of horizontal fins and the plurality of vertical fins has a thickness of between 0.15 mm and 0.2 mm; and
a vapor chamber portion configured to interface with a heat source to be cooled, wherein the vapor chamber portion includes, on a plurality of internal surfaces of the vapor chamber portion, a wicking structure configured to transfer a working fluid within the vapor chamber portion;
wherein the heatsink portion, the vapor chamber portion, and the wicking structure are portions of a same single printed monobody structure.

2. The device of claim 1, wherein the single printed monobody structure was printed using Direct Metal Laser Sintering.

3. The device of claim 1, wherein a first side of the vapor chamber portion is configured to interface the heat source and a second side of the vapor chamber portion opposite the first side is configured to interface with the heatsink portion.

4. (canceled)

5. The device of claim 1, wherein a top portion of the heatsink portion at least in part encloses the grid structure.

6. The device of claim 1, wherein the vapor chamber portion includes at least one slot to evacuate metal powder.

7. The device of claim 1, wherein the vapor chamber portion includes a charging port by which the vapor chamber portion is vacuum charged.

8. The device of claim 1, wherein the vapor chamber portion includes a plurality of support structures.

9. The device of claim 1, wherein the wicking structure includes grooved channels adapted to transport the working fluid.

10. The device of claim 1, wherein the wicking structure includes a mesh.

11. The device of claim 1, wherein at least one of the heatsink portion and the vapor chamber portion is copper.

12. The device of claim 1, wherein at least one of the heatsink portion and the vapor chamber portion is aluminum.

13. The device of claim 1, wherein at least a portion of the heatsink portion is made of a different material from at least a portion of a body of the vapor chamber portion.

14. The device of claim 1, wherein the heatsink portion includes a fin gap between 0.6 mm and 1.1 mm.

15. The device of claim 1, wherein the wicking structure is made by sintering metal powder particles.

16. A method, comprising:
applying metal powder;
sintering the applied metal powder to form a layer in a monobody integrated heatsink and vapor chamber structure, wherein a vapor chamber portion of the monobody structure includes on an internal surface of the vapor chamber portion a wicking structure configured to transfer a working fluid within the vapor chamber portion;
performing a stress relief cycle;
removing excess parts; and
machining to create a flat surface on a bottom of the monobody integrated heatsink and vapor chamber structure.

17. The method of claim 16, wherein performing the stress relief cycle includes:
removing the monobody integrated heatsink and vapor chamber structure from a fabrication piston; and
heating the monobody integrated heatsink and vapor chamber structure.

18. The method of claim 16, wherein removing excess parts includes evacuating trapped metal powder from the vapor chamber portion via a slot in the vapor chamber.

19. The method of claim 16, further comprising charging and sealing the vapor chamber portion.

20. A device, comprising:
a plurality of vertical fins arranged adjacent to each other with less than a 1.1 mm gap between adjacent fins;
a plurality of horizontal fins in thermal communication with the plurality of vertical fins and interleaved with the plurality of vertical fins to form a grid structure; and
a wicking structure provided on a plurality of internal surfaces of a vapor chamber portion, the vapor chamber portion configured to interface with the plurality of vertical fins and the plurality of horizontal fins;
wherein:
at least one fin of the plurality of horizontal fins and the plurality of vertical fins has a thickness of between 0.15 mm and 0.2 mm, and
the device has been manufactured using three-dimensional printing.
